(19) United States
(12) Patent Application Publication
(10) Pub. No.: US 2019/0043698 A1
(43) Pub. Date: Feb. 7, 2019

(54) ELECTROSTATIC SHIELD FOR SUBSTRATE SUPPORT

(71) Applicant: Applied Materials, Inc., Santa Clara, CA (US)

(72) Inventor: Vijay D. PARKHE, San Jose, CA (US)

(21) Appl. No.: 16/053,950

(22) Filed: Aug. 3, 2018

Related U.S. Application Data
(60) Provisional application No. 62/541,002, filed on Aug. 3, 2017.

(51) Int. Cl. H01J 37/32; C23C 16/455; C23C 16/52; H01L 21/687; H01L 21/673

(52) U.S. Cl. CPC H01J 37/32697; C23C 16/45536; H01J 37/32449; H01J 37/32458; C23C 16/52; H01J 2237/3341; H01L 21/68742; H01L 21/67383; H01J 37/32651; H01J 37/32724; H01J 2237/3321; C23C 16/45565

(57) ABSTRACT

Embodiments of the disclosure relate to a shield used within a plasma processing chamber. In one embodiment, a kit for shielding a substrate support is disclosed. The kit includes a plate having a central aperture and a hollow shell assembly configured to be coupled to the plate around the central aperture. The hollow shell assembly includes a plurality of shell portions removably coupled together. In another embodiment, a shielded substrate support includes a pedestal body having one or more heating elements, a hollow stem coupled to the pedestal body, a heater support coupled to the stem and a shield assembly coupled to the heater support. The shield assembly includes a plate having a central aperture and a hollow shell assembly configured to be coupled to the plate around the central aperture. The hollow shell assembly includes a plurality of shell portions removably coupled together.

### CROSS-REFERENCE TO RELATED APPLICATIONS

This application claims benefit of United States provisional patent application Ser. No. 62/541,002, filed Aug. 3, 2017, which is herein incorporated by reference.

### BACKGROUND

### Field

Embodiments of the disclosure generally relate to semiconductor manufacturing processes and apparatuses. More particularly, the disclosure relates to shields for substrate supports utilized in plasma processing chambers, and methods of use.

### Description of the Related Art

Semiconductor substrates undergo a variety of processes like implantation, etching and deposition of materials thereon during manufacturing. Many of these processes occur in presence of a plasma in and include, for example, etching, chemical vapor deposition (CVD) and physical vapor deposition (PVD), among others. In a conventional plasma-enhanced CVD (PECVD) process, a controlled plasma is formed to energize reactive species to produce a desired film on a semiconductor substrate. The substrate is held on a substrate support during processing. In some processes, such as PECVD processes, the substrate support includes a heater for controlling the temperature of the substrate to enhance deposition.

During plasma processing, the heater develops an electric potential, which leads to the formation of an electric field between the heater within the substrate support and the sidewalls and the bottom wall of the plasma processing chamber. The electric field may be sufficiently strong to produce a parasitic plasma between the substrate support and the adjacent surfaces of the processing chamber. The parasitic plasma causes an undesirable dissipation of RF power applied to the processing chamber for the generation of plasma between the substrate support and the lid of the chamber. Further, the parasitic plasma leads to the deposition of material on the sidewalls and the bottom wall of the processing chamber, resulting in undesirable contamination of the processing chamber and increased frequency of chamber cleaning for removal of the undesirable contamination. Moreover, parasitic plasmas may also result in arcing and erosion of chamber surfaces, both of which contribute to particulate contamination and reduced component life.

Thus, there is a need for an improved shield for a substrate support utilized in plasma processing chambers.

### SUMMARY

Embodiments of the disclosure relate to a shield assembly for a substrate support used in a plasma processing chamber.

In one embodiment, a kit for shielding a substrate support is disclosed. The kit includes a plate having a central aperture and a hollow shell assembly configured to be coupled to the plate around the central aperture. The hollow shell assembly includes a plurality of shell portions removably coupled together. The plate is configured to cover a surface of a pedestal body. The hollow shell assembly is configured to surround a stem extending from the pedestal body.

In another embodiment of the disclosure, a shielded substrate support is disclosed. The shielded substrate support includes a pedestal body having one or more heating elements and a hollow stem coupled to the pedestal body. The shield assembly includes a plate configured to cover a bottom surface of the pedestal body and a hollow shell assembly. The plate has a central aperture. The hollow shell assembly is configured to be coupled to the plate around the central aperture at a first end and to the heater support at the second end. The hollow shell assembly includes a plurality of shell portions removably coupled together around the stem.

In yet another embodiment of the disclosure, a plasma processing chamber is disclosed. The plasma processing chamber includes a chamber body defining a chamber volume therein. A shielded substrate support is disposed within the chamber volume. The shielded substrate support includes a pedestal body having one or more heating elements, a hollow stem coupled to the pedestal body, and a shield assembly. The shield assembly includes a plate configured to cover a bottom surface of the pedestal body and a hollow shell assembly. The plate has a central aperture. The hollow shell assembly is configured to be coupled to the plate around the central aperture at a first end. The hollow shell assembly includes a plurality of shell portions removably coupled together around the stem.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and as the disclosure may admit to other equally effective embodiments.

FIG. 1 is a schematic, cross-sectional view of a plasma processing chamber using a heater covered by an electrostatic shield.

FIG. 2 is a perspective view of a plate comprising part of the electrostatic shield.

FIG. 3 is bottom view of the plate comprising part of the electrostatic shield.

FIG. 4 is a perspective view of a shell comprising part of the electrostatic shield.

FIG. 5 is a side view of the shell comprising part of the electrostatic shield.

FIG. 6 is a top view of the bottom surface of the shell comprising part of the electrostatic shield.

FIG. 7 is a perspective view of the assembled electrostatic shield.

To facilitate understanding, identical reference numerals have been used, where possible, to designate identical elements that are common to the figures. It is contemplated that elements and features disclosed in one embodiment may be beneficially incorporated in other embodiments without specific recitation.

### DETAILED DESCRIPTION

The disclosure described herein demonstrates a method and an apparatus for shielding a substrate support for use in a plasma processing chamber. The apparatus, in the form of a shield, reduces the strength of an electric field present between the substrate support and adjacent surfaces of the plasma processing chamber. The reduced strength of the electric field substantially prevents the formation of parasitic plasma between the substrate support and adjacent surfaces of the plasma processing chamber, thus reducing stray deposition of material, particle generation, potential arcing and erosion of chamber components. The reduced strength of the electric field substantially also prevents the undesirable dissipation of RF power coupled to the plasma processing chamber utilized to drive deposition on a substrate disposed on the substrate support within the chamber.

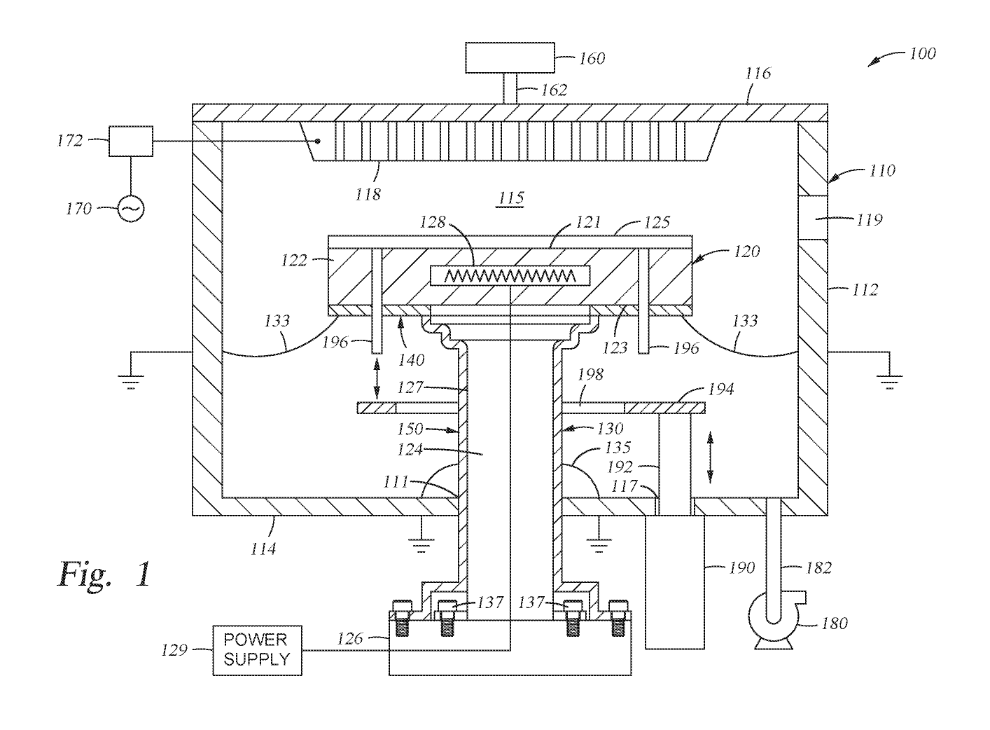

FIG. 1 is a schematic, cross-sectional view of a plasma processing chamber 100. The plasma processing chamber 100 may be a Chemical Vapor Deposition (CVD) chamber, or other suitable plasma processing chamber. Examples of plasma processing chamber 100 that may be adapted to benefit from the disclosure include Plasma-Enhanced Chemical Vapor Deposition (PECVD) chambers, such as but not limited to the CENTURA® chamber, PRODUCER® chamber, the PRODUCER® GT chamber, the PRODUCER® XP Precision™ chamber and the PRODUCER® SE™ chamber which are available from Applied Materials, Inc., of Santa Clara, Calif. It is contemplated that plasma processing chambers from other manufacturers may also be adapted to benefit from the disclosure. Although FIG. 1 described herein is illustrative of a PECVD chamber, the plasma processing chamber 100 is for illustrative purposes and should not be construed or interpreted as limiting the scope of the embodiments described herein. The embodiments described herein can be equally applied to those chambers utilized for PVD, etching, implanting, annealing, and plasma-treating materials on semiconductor substrates, among others.

As shown in FIG. 1, the plasma processing chamber 100 includes a chamber body 110 having an interior volume 115. The chamber body 110 has a sidewall 112, a bottom wall 114 and a lid 116. The sidewall 112, the bottom wall 114 and the lid 116 may be formed from conductive materials, such as aluminum or stainless steel. The sidewall 112 and bottom wall 114 are electrically grounded during operation of the plasma processing chamber 100.

The chamber body 110 has a port 119 for loading one or more substrates 125 on a substrate support 120 in the plasma processing chamber 100. The port 119 is also used for unloading substrates 125 from the substrate support 120. A gas panel 160 is fluidly connected by a conduit 162 to the interior volume 115 to provide one or more process gases for plasma generation within the processing chamber 100. A pump 180 is fluidly connected by a conduit 182 to the interior volume 115 to pump out the process gases and to maintain vacuum conditions within the interior volume 115 during the plasma process.

In one example, the plasma processing chamber 100 includes a showerhead 118 for introduction of one or more process gases into the interior volume 115. In other examples, one or more nozzles may be utilized to for introduce the process gases into the interior volume 115 of the processing chamber 100. The showerhead 118 is coupled to the lid 116 such that the process gases from the gas panel 160 enter the interior volume 115 through the showerhead 118.

An RF power source 170 is coupled to the showerhead 118 through an impedance matching circuit 172. The RF power source 170 is configured to provide power for sustaining a plasma formed from the process gases within the interior volume 115 of the chamber 100 that is utilized to process the substrate disposed on the substrate support 120.

The substrate support 120 is disposed within the interior volume 115. The substrate support 120 has a hollow stem 124 and a pedestal body 122 coupled to the stem 124. The stem 124 is mechanically coupled to a heater support 126 by a securing mechanism. In some embodiments, the securing mechanism may be one or more fasteners, such as screws 137.

The pedestal body 122 has a top surface 121 and a bottom surface 123. The stem 124 has a sidewall 127. The stem 124 passes through a first passage 111 formed through the bottom wall 114. A rod 192 connected to an actuator 190 passes through a second passage 117 formed through the bottom wall 114. The rod 192 is coupled to a lift plate 194 having an aperture 198 accommodating the stem 124 of the substrate support 120. Lift pins 196 are disposed through the pedestal body 122. The actuator 190 actuates the rod 192 such that the lift plate 194 is moved up or down to extend or retract the lift pins 196 through the pedestal body 122. The pedestal body 122 may also be raised or lowered within the interior volume 115 of the processing chamber 100 to control the spacing between the substrate 125 disposed on the substrate support 120 and the showerhead 118. The pedestal body 122 has a resistive heating element 128 embedded therein. An electric power supply 129 is coupled to the resistive heating element 128 through the stem 124.

A shield assembly 130 (also referred to as the shield 130) covers the bottom surface 123 of the pedestal body 122 and the sidewall 127 of the stem 124. The shield assembly 130 includes a plate 140 and a hollow shell assembly 150. The plate 140 covers the bottom surface 123 of the pedestal body 122. The plate 140 may optionally be connected to the sidewall 112 of the chamber 100 through one or more ground straps 133, thus providing a shortened and robust RF return path between the substrate support 120 and the chamber body 110 which reduces the electrical potential between the substrate support 120 and the chamber body 110. The reduced electrical potential significantly reduces the potential for arcing and parasitic plasma generation between the substrate support 120 and the chamber body 110. The hollow shell assembly 150 covers the sidewall 127 of the stem 124, and may be disposed in contact with the outer surface of the sidewall 127. The hollow shell assembly 150 is connected to the bottom wall 114 of the processing chamber 100 through one or more ground straps 135 and is thus electrically grounded. Alternatively, the hollow shell assembly 150 may be electrically connected to the chamber body 110 through the plate 140, or the plate 140 may be electrically connected to the chamber body 110 through the hollow shell assembly 150.

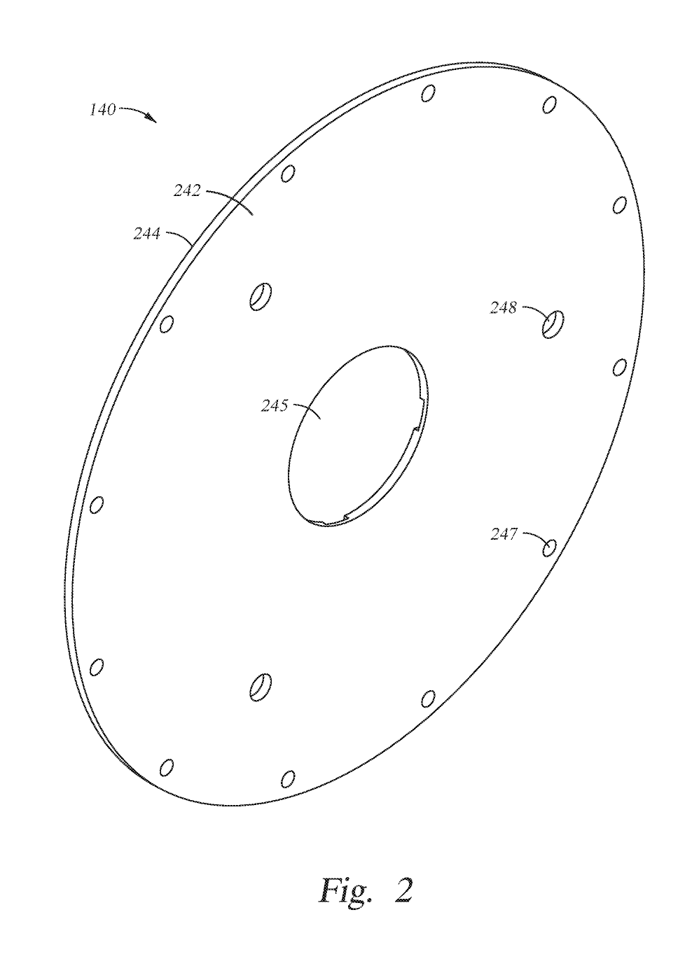

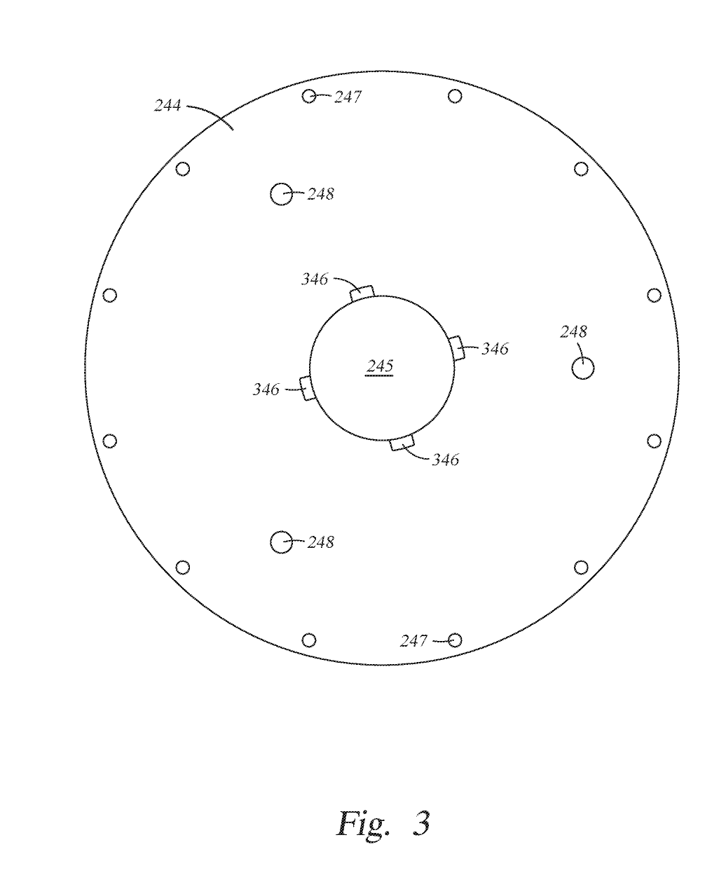

FIG. 2 is a perspective view of the plate 140 of the shield assembly 130. The plate 140 is fabricated from an electrically conductive material. Conductive materials suitable for fabricating the plate 140 include, but are not limited to, silicon carbide, a fluorine-resistant conductive material or a conductive material having a fluorine-resistant coating. The plate 140 has a top surface 242 and a bottom surface 244. The top surface 242 is configured to contact with and cover the bottom surface 123 of the pedestal body 122. The plate 140 has a central aperture 245. The plate 140 may include one or more peripheral holes 247. The plate 140 is configured to be grounded by one or more ground straps 133 (shown in FIG. 1) coupled to the one or more peripheral holes 247. The plate 140 has three or more lift pin holes 248 through which the lift pins 196 extend between the top surface 121 and the bottom surface 123 of the pedestal body 122. The bottom surface 244 of the plate 140 faces the bottom wall 114 of the chamber 100 and is coupled to the hollow shell assembly 150 of the shield assembly 130. The bottom surface 244 has one or more notches 346 formed about the edge of the central aperture 245, as shown in FIG. 3. In some embodiments, the plate 140 is disk-shaped, though in other embodiments, the plate 140 may have a polygonal shape.

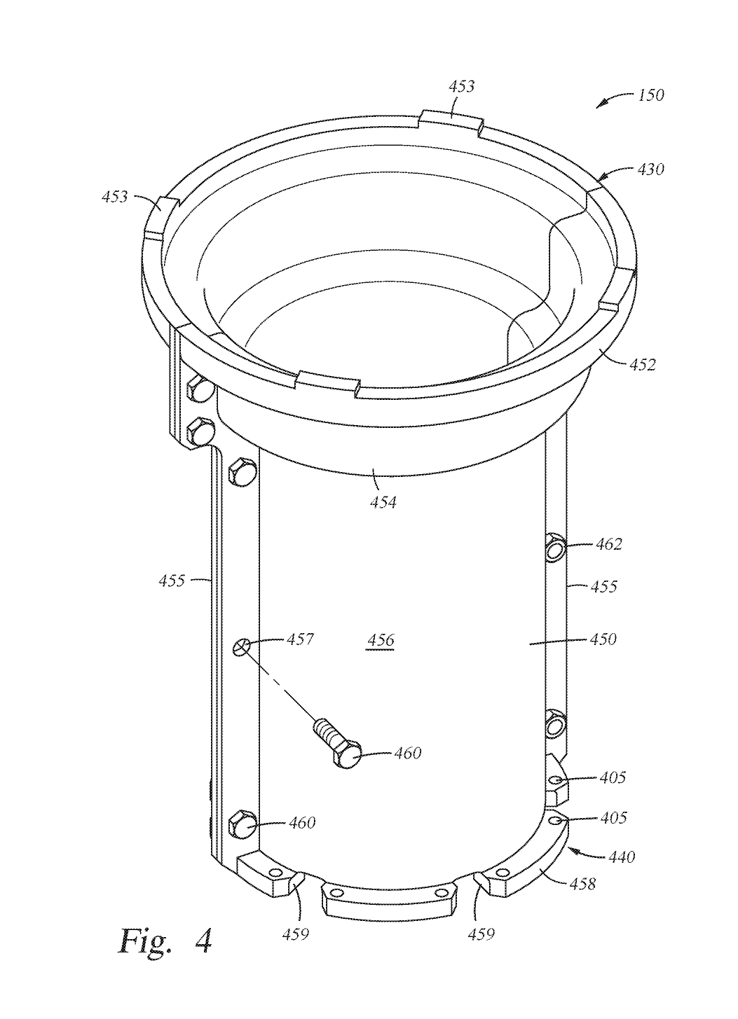

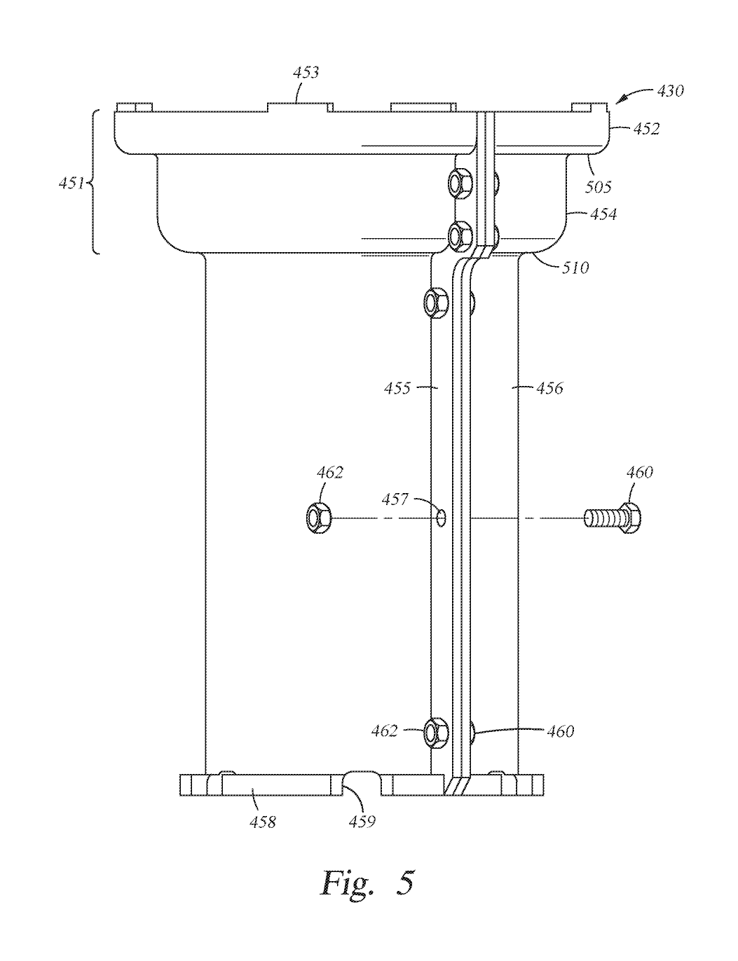

FIGS. 4 and 5 are respectively perspective and side views of the hollow shell assembly 150 of the shield assembly 130 configured to be coupled to the plate 140 around the central aperture 245 at a first end 430 of the hollow shell assembly 150. The hollow shell assembly 150 is fabricated from a conductive material. Conductive materials suitable for fabricating the hollow shell assembly 150 include, but are not limited to, silicon carbide, a fluorine-resistant conductive material or a conductive material having a fluorine-resistant coating. The hollow shell assembly 150 is coupled to the heater support 126 at a second end 440.

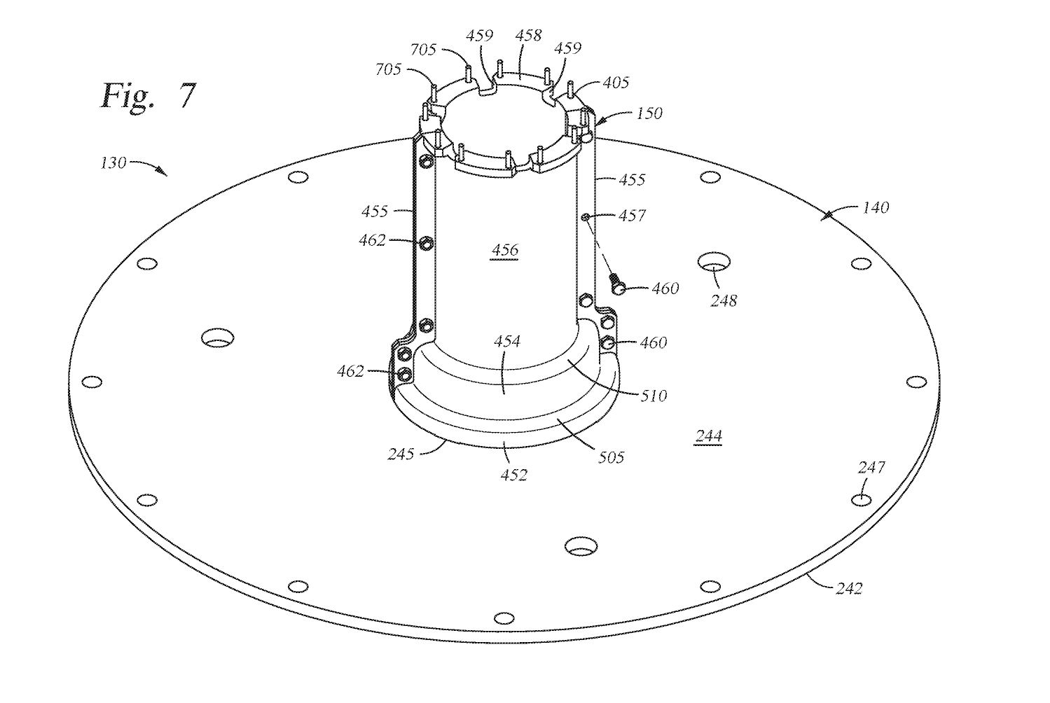

The hollow shell assembly 150 has a plurality of shell portions 450 removably coupled together to the form the hollow shell assembly 150. In one example, the shell portions 450 are individual arcuate shapes which couple together to complete a tubular member. Each shell portion 450 has a top portion 451, an elongated central portion 456 and a bottom portion 458. The top portion 451 has an upper portion 452 and a lower portion 454. The upper portion 452 has a diameter greater than a diameter of the central aperture 245 as well as a diameter of the lower portion 454. The upper portion 452 of the top portion 451 has a number of protrusions 453 that can be received by the notches 346 on the central aperture 245 of the plate 140, thus coupling the plate 140 to the hollow shell assembly 150 formed by the shell portions 450. The upper portion 452 transitions to the lower portion 454 through a step 505. The lower portion 454 transitions to the central portion 456 through another step 510. The central portion 456 has a diameter less than the diameters of the upper portion 452 and the lower portion 454 of the top portion 451. The bottom portion 458 is located at the second end 440. The bottom portion 458 extends from the central portion 456 and has a diameter greater than the diameter of the central portion 456. The bottom portion 458 has a plurality of tunnels 459 to accommodate the bottom portion 458 over the screws 137 that couple the stem 124 to the heater support 126. The bottom portion 458 has a plurality of holes 405 through which the bottom portion 458 is mechanically coupled to the heater support 126 by a securing mechanism. In some embodiments, the securing mechanism may be one or more screws 705, as shown in FIG. 7. In some embodiments, the hollow shell assembly 150 is cylindrical-shaped and accordingly, the shell portions 450 have curved surfaces that form a cylindrical surface when coupled together to surround the stem 124.

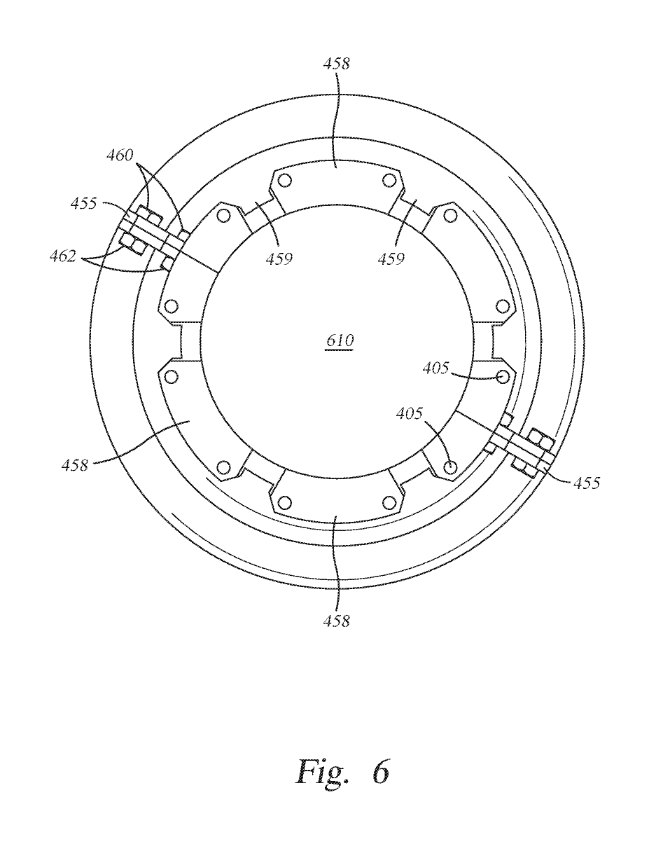

The top portion 451, the central portion 456 and the bottom portion 458 of the shell portion 450 have two longitudinal flanges 455 running along the edges of each of the shell portions 450. The flanges 455 have a plurality of holes 457 that are aligned with another plurality of holes 457 on the flanges 455 of the adjacent shell portion 450. The shell portions 450 are mechanically coupled to form the hollow shell assembly 150 that has an aperture 610, as shown in FIG. 6. The aperture 610 runs through the top portion 451, the central portion 456 and the bottom portion 458 such that the central axis of the aperture 610 aligns with the central axis of the central aperture 245 of the plate 140. In some embodiments, one or more screws 460, having corresponding nuts 462, are placed through the plurality of holes 457 to couple adjacent shell portions 450.

The shield assembly 130 described herein can be advantageously used to cover the substrate support 120 in order to reduce the strength of electric fields present between the substrate support 120 and adjacent surfaces of the plasma processing chamber 100, such as the sidewall 112 and the bottom wall 114. As mentioned above, the reduced strength of the electric field substantially prevents formation of parasitic plasma between the substrate support and adjacent surfaces of the plasma processing chamber, thus reducing stray deposition of material, particle generation, potential arcing and erosion of chamber components, as well as the undesirable dissipation of RF power coupled to the plasma processing chamber 100 utilized to drive deposition on the substrate disposed in the chamber 100.

After the substrate support 120 is assembled but before the substrate support 120 is installed within the plasma processing chamber 100, the substrate support shield assembly 130 is secured to the substrate support 120. With reference to FIG. 1, the plate 140 is disposed on the bottom surface 123 of the pedestal body 122 such that the lift pins 196 may pass through the pin holes 248. As the plate 140 is secured against the bottom surface 123, the peripheral holes 247 are positioned along the edge of the bottom surface 123 to enable an easy connection between the ground straps 133 and the sidewall 112 of the chamber 100.

The shell portions 450 are assembled around the stem 124 of the substrate support 120. Adjacent shell portions 450 are mechanically coupled to each other, for example by the screws 460 passing through the plurality of holes 457 on the flanges 455 of adjacent shell portions 450 and engaging with the washers 462. The shell portions 450 thus coupled wrap around the stem 124 to form the hollow shell assembly 150 of the shield assembly 130.

The protrusions 453 on the top portion 451 of the shell portions 450 are mated with the notches 346 formed on the bottom surface 244 of the plate 140 such that the plate 140 and the hollow shell assembly 150 are secured in a predefined position relative to each other. In one embodiment, the protrusions 453 may be pressed fit into the notches 346 to provide good electric connection between the shell portions 450 and the plate 140.

The hollow shell assembly 150 is mechanically coupled to the heater support 126, for example using screws 705 through the holes 405 that engage with threaded holes formed in the heater support 126. One or more ground straps 133, if utilized, are coupled to the peripheral holes 247 and connected to the grounded sidewall 112 of the chamber 100. One or more ground straps 135, if utilized, may be coupled to one or more holes 457 on the flanges 455 and connected to the grounded bottom wall 114 of the chamber 100.

The shield assembly described herein, offers several advantages that improve the plasma processing of substrates placed on the substrate support. During plasma processing, the substrate support develops an electric potential, which leads to the formation of an electric field between the substrate support and the adjacent surfaces of the plasma processing chamber. In conventional processing chambers, the electric field may be sufficiently strong to produce a parasitic plasma in the area between the substrate support and the adjacent surfaces of the plasma processing chamber. The parasitic plasma thus formed leads to unwanted stray deposition of material on the sidewalls and the bottom wall of the chamber, particle generation, potential arcing issues and increased chamber erosion. The shield, placed around the substrate support substantially inhibits the formation of strong electric fields such that the formation of parasitic plasma in the area between the substrate support and the adjacent surfaces of the plasma processing chamber is significantly reduced or even eliminated.

Further, since the shield significantly reduces or eliminates the formation of parasitic plasma in the area between the substrate support and the adjacent surfaces of the plasma processing chamber, the undesirable dissipation of RF power coupled to the plasma processing chamber utilized to drive the substrate processing is substantially reduced. As a result, more RF power is available for generation and control of the plasma driving substrate processing, resulting in higher efficiency, faster deposition rates, reduced particle generation, increased substrate yield, longer chamber component life and better quality of plasma processing of semiconductor substrates.

While the foregoing is directed to particular embodiments of the present disclosure, it is to be understood that these embodiments are merely illustrative of the principles and applications of the present disclosure. It is therefore to be understood that numerous modifications may be made to the illustrative embodiments to arrive at other embodiments without departing from the spirit and scope of the present disclosure, as defined by the appended claims.

What is claimed is:

1. A kit for shielding substrate supports, comprising:
a plate having a central aperture, the plate configured to cover a surface of a pedestal body; and
a hollow shell assembly configured to be coupled to the plate, the hollow shell assembly comprising a plurality of shell portions removably coupled together configured to surround a stem extending from the pedestal body.

2. The kit of claim 1, wherein the plate further comprises:
a plurality of peripheral holes configured to couple with one or more ground straps.

3. The kit of claim 1, wherein at least one of the shell portions comprises:
a plurality of holes configured to couple with a heater support.

4. The kit of claim 1, wherein the hollow shell assembly further comprises:
a top portion having a diameter greater than a diameter of the central aperture, the top portion configured to attach to the central aperture;
an elongated central portion extending from the top portion, the elongated central portion having a diameter less than the diameter of the top portion; and
a bottom portion extending from the elongated central portion, the bottom portion having a diameter greater than the diameter of the elongated central portion.

5. The kit of claim 1, wherein the plate is fabricated from silicon carbide, a fluorine-resistant conductive material or a conductive material having a fluorine-resistant coating.

6. The kit of claim 1, wherein the hollow shell assembly is fabricated from silicon carbide, a fluorine-resistant conductive material or a conductive material having a fluorine-resistant coating.

7. The kit of claim 1, wherein the plate has a disk shape.

8. The kit of claim 1, wherein the hollow shell assembly has a cylindrical shape.

9. The kit of claim 1, wherein the central aperture has one or more notches configured to receive one or more protrusions extending from the hollow shell assembly.

10. A shielded substrate support, comprising:
a pedestal body comprising one or more heating elements;
a hollow stem coupled to the pedestal body; and
a shield assembly comprising:
a plate configured to cover a bottom surface of the pedestal body, the plate comprising a central aperture; and
a hollow shell assembly configured to be coupled to the plate around the central aperture at a first end and to the heater support at a second end, the hollow shell assembly comprising a plurality of shell portions removably coupled together around the stem.

11. The substrate support of claim 10, wherein the hollow shell assembly further comprises:
a top portion having a diameter greater than a diameter of the central aperture, the top portion configured to attach to the central aperture;
an elongated central portion extending from the top portion, the elongated central portion having a diameter less than the diameter of the top portion; and
a bottom portion extending from the elongated central portion, the bottom portion having a diameter greater than the diameter of the elongated central portion.

12. The substrate support of claim 10, wherein the plate is fabricated from silicon carbide, a fluorine-resistant conductive material or a conductive material having a fluorine-resistant coating.

13. The substrate support of claim 10, wherein the hollow shell assembly is fabricated from silicon carbide, a fluorine-resistant conductive material or a conductive material having a fluorine-resistant coating.

14. The substrate support of claim 10, wherein the central aperture has one or more notches configured to receive one or more protrusions extending from the hollow shell assembly.

15. A plasma processing chamber comprising:
a chamber body defining a chamber volume therein; and
a shielded substrate support disposed within the chamber volume, the shielded substrate support comprising:
a pedestal body comprising one or more heating elements;
a hollow stem coupled to the pedestal body; and
a shield assembly comprising:
a plate configured to cover a bottom surface of the pedestal body, the plate comprising a central aperture; and
a hollow shell assembly configured to be coupled to the plate around the central aperture at a first end, the hollow shell assembly comprising a plurality of shell portions removably coupled together around the stem.

16. The plasma processing chamber of claim 15 further comprising:
a heater support coupled to a second end of the hollow shell assembly opposite of the first end.

17. The plasma processing chamber of claim 15, wherein the hollow shell assembly further comprises:
a top portion having a diameter greater than a diameter of the central aperture, the top portion configured to attach to the central aperture;
an elongated central portion extending from the top portion, the elongated central portion having a diameter less than the diameter of the top portion; and
a bottom portion extending from the elongated central portion, the bottom portion having a diameter greater than the diameter of the elongated central portion.

18. The plasma processing chamber of claim 15, wherein the plate is fabricated from silicon carbide, a fluorine-resistant conductive material or a conductive material having a fluorine-resistant coating.

19. The plasma processing chamber of claim 15, wherein the hollow shell assembly is fabricated from silicon carbide, a fluorine-resistant conductive material or a conductive material having a fluorine-resistant coating.

20. The plasma processing chamber of claim 15, wherein the central aperture has one or more notches configured to receive one or more protrusions extending from the hollow shell assembly.
